(19) United States
(12) Patent Application Publication
(10) Pub. No.: US 2025/0287716 A1
(43) Pub. Date: Sep. 11, 2025

(54) PHOTOELECTRIC CONVERSION APPARATUS, PHOTOELECTRIC CONVERSION SYSTEM, MOVING BODY, AND EQUIPMENT

(71) Applicant: CANON KABUSHIKI KAISHA, Tokyo (JP)

(72) Inventor: KAZUHIRO MORIMOTO, Kanagawa (JP)

(21) Appl. No.: 19/056,963

(22) Filed: Feb. 19, 2025

(30) Foreign Application Priority Data
Mar. 6, 2024 (JP) 2024-034179

(51) Int. Cl. H10F 39/00

(52) U.S. Cl. CPC H10F 39/809; H10F 39/018; H10F 39/811

(57) ABSTRACT

A back-illuminated type photoelectric conversion apparatus in which a first semiconductor layer including an APD array in which a plurality of avalanche photodiodes (APDs) are arranged, a second semiconductor layer including a plurality of first pixel circuits respectively for the plurality of APDs, a third semiconductor layer including a plurality of second pixel circuits respectively for the plurality of first pixel circuits, and a fourth semiconductor layer including a processing circuit configured to process signals output from the plurality of second pixel circuits are stacked is provided. The second semiconductor layer is arranged between the first semiconductor layer and the fourth semiconductor layer, and the third semiconductor layer is arranged between the second semiconductor layer and the fourth semiconductor layer. A through via extending through the third semiconductor layer is arranged in a region not overlapping the APD array.

### BACKGROUND

### Technical Field

The present disclosure relates to a photoelectric conversion apparatus, a photoelectric conversion system, a moving body, and equipment.

### Description of the Related Art

An avalanche photodiode (APD) capable of detecting light at the single photon level is known. Japanese Patent Laid-Open No. 2022-113123 discloses a photoelectric conversion apparatus in which a first substrate including a plurality of pixels with APDs, a second substrate including a plurality of pixel circuits provided in correspondence with the plurality of pixels, and a third substrate including a signal processing circuit that processes signals output from the plurality of pixel circuits are stacked.

A photoelectric conversion apparatus is demanded to increase the number of pixels, achieve integration, and improve functionality.

### SUMMARY

According to some embodiments, a back-illuminated type photoelectric conversion apparatus in which a first semiconductor layer including an APD array in which a plurality of avalanche photodiodes (APDs) are arranged, a second semiconductor layer including a plurality of first pixel circuits respectively for the plurality of APDs, a third semiconductor layer including a plurality of second pixel circuits respectively for the plurality of first pixel circuits, and a fourth semiconductor layer including a processing circuit configured to process signals output from the plurality of second pixel circuits are stacked, wherein the second semiconductor layer is arranged between the first semiconductor layer and the fourth semiconductor layer, the third semiconductor layer is arranged between the second semiconductor layer and the fourth semiconductor layer, and a through via extending through the third semiconductor layer is arranged in a region not overlapping the APD array, is provided.

According to some embodiments of the present disclosure, it is possible to provide a technique advantageous in improving performance of a photoelectric conversion apparatus.

Further features of the present invention will become apparent from the following description of exemplary embodiments with reference to the attached drawings.

### BRIEF DESCRIPTION OF THE DRAWINGS

FIG. 1 is a view showing an example of the configuration of a photoelectric conversion apparatus according to an embodiment.

FIGS. 2A to 2D are views each showing an example of the configuration of each semiconductor layer of the photoelectric conversion apparatus shown in FIG. 1.

FIG. 3 is a circuit diagram showing an example of the configuration of the pixel of the photoelectric conversion apparatus shown in FIG. 1.

FIGS. 4A and 4B show a circuit diagram and timing charts for explaining an example of the operation of the pixel of the photoelectric conversion apparatus shown in FIG. 1.

FIGS. 5A to 5I are views for explaining selection of the stacked structure of the photoelectric conversion apparatus shown in FIG. 1.

FIG. 6 is a sectional view showing an example of the configuration of the photoelectric conversion apparatus shown in FIG. 1.

FIG. 7 is a sectional view showing an example of the manufacturing step of the photoelectric conversion apparatus shown in FIG. 6.

FIG. 8 is a sectional view showing an example of the configuration of the photoelectric conversion apparatus shown in FIG. 1.

FIG. 9 is a sectional view showing an example of the manufacturing step of the photoelectric conversion apparatus shown in FIG. 8.

FIG. 10 is a sectional view showing an example of the configuration of the photoelectric conversion apparatus shown in FIG. 1.

FIG. 11 is a sectional view showing an example of the configuration of the photoelectric conversion apparatus shown in FIG. 1.

FIG. 12 is a block diagram showing a photoelectric conversion system using the photoelectric conversion apparatus according to the embodiment.

FIGS. 13A and 13B are a block diagram and a view showing a photoelectric conversion system using the photoelectric conversion apparatus according to the embodiment.

FIG. 14 is a view showing a photoelectric conversion system using the photoelectric conversion apparatus according to the embodiment.

FIG. 15 is a view showing a photoelectric conversion system using the photoelectric conversion apparatus according to the embodiment.

FIGS. 16A and 16B are views each showing a photoelectric conversion system using the photoelectric conversion apparatus according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

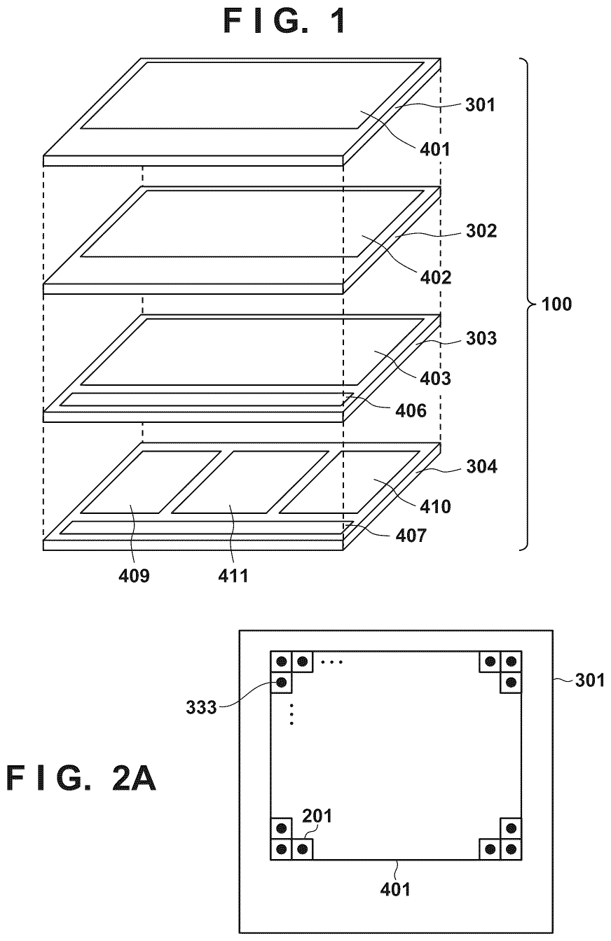

A photoelectric conversion apparatus according to an embodiment of the present disclosure will be described first with reference to FIGS. 1 to 11. FIG. 1 is a view showing an example of the configuration of a photoelectric conversion apparatus 100 according to this embodiment.

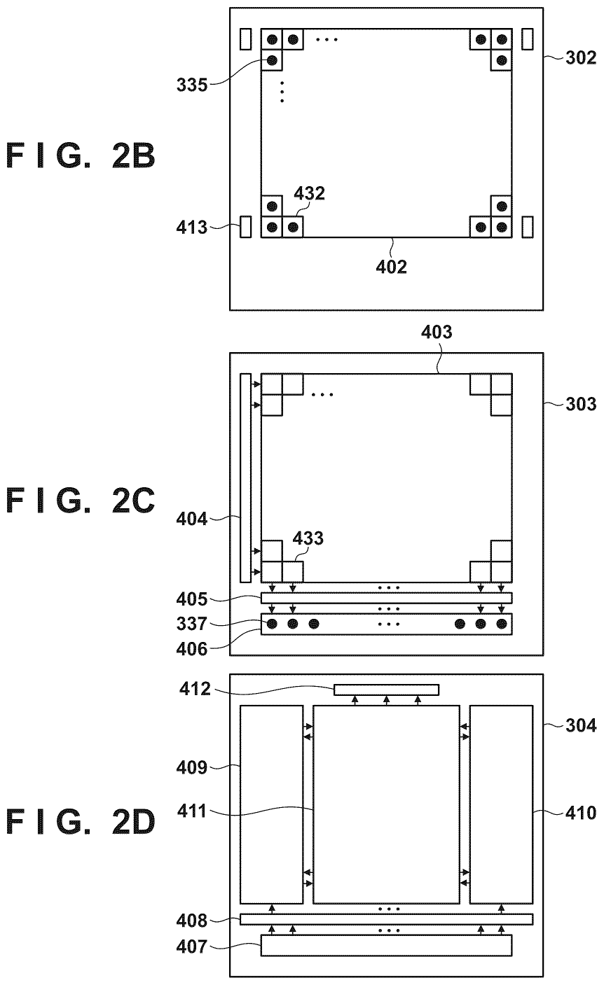

The photoelectric conversion apparatus 100 is formed by stacking four semiconductor layers 301 to 304 (to be also referred to as substrates hereinafter) and electrically connecting them. The semiconductor layer 301 includes an APD array 401 in which a plurality of avalanche photodiodes (APDs) 201 (shown in FIG. 2A) are arranged. The semiconductor layer 302 includes a pixel circuit array 402 in which a plurality of pixel circuits respectively for the plurality of APDs 201 are arranged. The semiconductor layer 303 includes a pixel circuit array 403 in which a plurality of pixel circuits respectively for the plurality of pixel circuits arranged in the semiconductor layer 302 are arranged. In addition, a signal transfer unit 406 for transferring signals output from the plurality of pixel circuits arranged in the semiconductor layer 303 to the semiconductor layer 304 is arranged in the semiconductor layer 303. The semiconductor layer 304 includes a processing circuit 411 for processing signals output from the plurality of pixel circuits arranged in the semiconductor layer 303. In addition, memories 409 and 410 that store signals output from the plurality of pixel circuits arranged in the semiconductor layer 303 and the like are arranged in the semiconductor layer 304. As shown in FIG. 1, the semiconductor layer 302 is arranged between the semiconductor layers 301 and 304 and the semiconductor layer 303 is arranged between the semiconductor layers 302 and 304.

FIGS. 2A to 2D are views each showing an example of the arrangement of components in each of the semiconductor layers 301 to 304. As shown in FIG. 2A, the semiconductor layer 301 includes the APD array 401 in which the plurality of APDs 201 are arranged to form a plurality of rows and a plurality of columns. The APD 201 is typically arranged to generate an image but need not always generate an image when it is used in a Time of Flight (ToF) distance measurement device. That is, the APD 201 may be configured to measure the time when light arrives and the amount of light. Furthermore, as shown in FIG. 2A, a connection portion 333 for connecting the APD 201 arranged in the semiconductor layer 301 and a pixel circuit 432 arranged in the semiconductor layer 302 is arranged between the semiconductor layers 301 and 302 to overlap the APD 201. The arrangement of the connection portion 333 will be described later.

As shown in FIG. 2B, the semiconductor layer 302 includes the pixel circuit array 402 in which the plurality of pixel circuits 432 are arranged to form a plurality of rows and a plurality of columns. With respect to the plurality of pixel circuits 432, one pixel circuit 432 may be arranged in correspondence with each of the plurality of APDs 201. This specification assumes that one APD 201 and one pixel circuit 432 have a correspondence relationship but the present invention is not limited to this. One pixel circuit 432 may be arranged in correspondence with one group constituted by a predetermined number of APDs 201 among the plurality of APDs 201. Details of the pixel circuit 432 will be described later. Furthermore, as shown in FIG. 2B, a connection portion 335 for connecting the pixel circuit 432 arranged in the semiconductor layer 302 and a pixel circuit 433 arranged in the semiconductor layer 303 is arranged between the semiconductor layers 302 and 303 to overlap the pixel circuit 432. The arrangement of the connection portion 335 will be described later.

As shown in FIG. 2B, a temperature measurement unit 413 may be provided in the semiconductor layer 302. The temperature measurement unit 413 can be a sensor for measuring the temperature. The characteristic of the APD 201 may change along with a change of the temperature. Therefore, the temperature may be measured in the semiconductor layer 302 close to the semiconductor layer 301 in which the APD 201 is arranged, and may be applied to driving control of the APD 201, control of a voltage to be applied to the APD 201, correction of a signal output from the APD 201, and the like. The temperature measurement unit 413 may be arranged in the semiconductor layer 301.

As shown in FIG. 2C, the semiconductor layer 303 includes the pixel circuit array 403 in which the plurality of pixel circuits 433 are arranged to form a plurality of rows and a plurality of columns. With respect to the plurality of pixel circuits 433, one pixel circuit 433 may be arranged in correspondence with each of the plurality of pixel circuits 432. Furthermore, for example, one pixel circuit 433 may be arranged in correspondence with one group constituted by a predetermined number of pixel circuits 432 among the plurality of pixel circuits 432. As described above, the signal transfer unit 406 for transferring the signals output from the plurality of pixel circuits 433 arranged in the semiconductor layer 303 to the semiconductor layer 304 is arranged in the semiconductor layer 303. As shown in FIG. 2C, connection portions 337 for connecting the signal transfer unit 406 arranged in the semiconductor layer 303 and a signal reception unit 407 arranged in the semiconductor layer 304 are arranged between the semiconductor layers 303 and 304 to overlap the signal transfer unit 406. The arrangement of the connection portions 337 will be described later.

A scanning circuit 404 and a readout circuit 405 are further arranged in the semiconductor layer 303. In the configurations shown in FIG. 2A to 2C, one APD 201, one pixel circuit 432, and one pixel circuit 433 are combined to form one so-called “pixel”. The scanning circuit 404 and the readout circuit 405 operate each pixel in cooperation with each other, thereby operating to read out a signal from the pixel. The scanning circuit 404 and the readout circuit 405 can be controlled by, for example, a control unit 408 arranged in the semiconductor layer 304 shown in FIG. 2D. In FIGS. 2C and 2D, control of each pixel formed by the APD 201, the pixel circuit 432, and the pixel circuit 433 and the flow of the signal from each pixel are indicated by arrows.

As shown in FIG. 2D, the semiconductor layer 304 includes the processing circuit 411 for processing the signals output from the plurality of pixel circuits 433 arranged in the semiconductor layer 303. It can be said that the processing circuit 411 processes the signal output from the pixel formed by the APD 201, the pixel circuit 432, and the pixel circuit 433. Furthermore, the memories 409 and 410 that store the signals and the like are arranged in the semiconductor layer 304. In the configuration shown in FIG. 2D, the two memories 409 and 410 are arranged in the semiconductor layer 304. However, only one memory or three or more memories may be arranged.

In addition, the signal reception unit 407, the control unit 408, and an output unit 412 are arranged in the semiconductor layer 304. The signal reception unit 407 receives the signal output from the signal transfer unit 406 arranged in the semiconductor layer 303. In a planar view, the signal transfer unit 406 and the signal reception unit 407 may be arranged along the long side of the APD array 401, as shown in FIGS. 2A, 2C, and 2D. This makes it possible to efficiently arrange more through vias and the more connection portions 337 for connecting the signal transfer unit 406 and the signal reception unit 407, as compared to a case where the signal transfer unit 406 and the signal reception unit 407 are arranged along the short side of the APD array 401. As a result, it is possible to increase the number of parallel transmissions of the signals output from the pixels each formed by the APD 201, the pixel circuit 432, and the pixel circuit 433, thereby speeding up data transmission. The control unit 408 controls the respective components arranged in the photoelectric conversion apparatus 100. Thus, the signal reception unit 407 can function as an output unit for transferring a control signal output from the control unit 408 to the semiconductor layers 301 to 303. The output unit 412 is arranged to output a signal generated by the photoelectric conversion apparatus 100 to the outside of the photoelectric conversion apparatus 100. In addition, the output unit 412 may function as an input unit that receives, from the outside of the photoelectric conversion apparatus 100, a signal for controlling the photoelectric conversion apparatus 100. That is, the output unit 412 can function as an interface between the photoelectric conversion apparatus 100 and an apparatus arranged outside the photoelectric conversion apparatus 100.

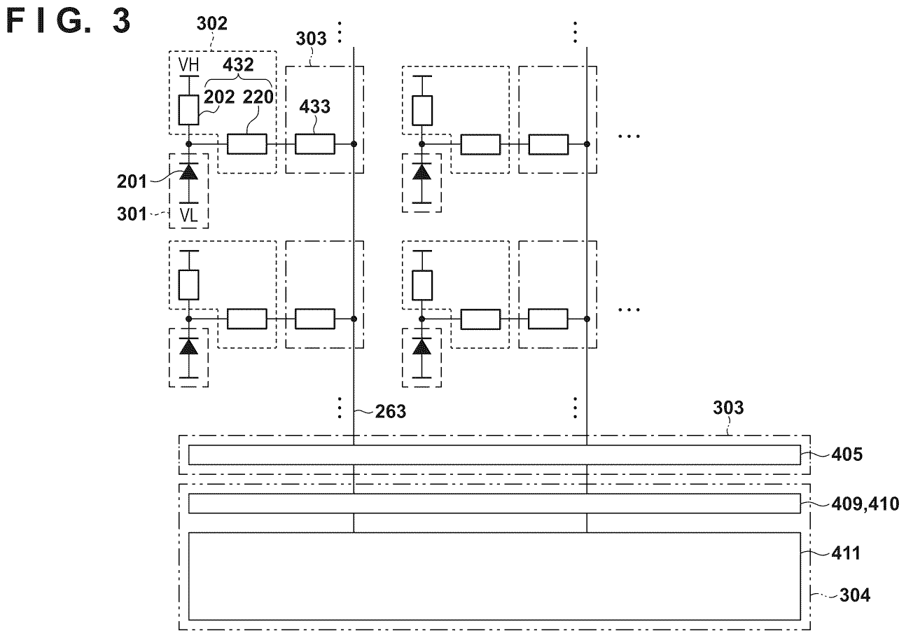

FIG. 3 is a circuit diagram including an equivalent circuit that focuses on four pixels (each pixel is formed by a combination of the APD 201, the pixel circuit 432, and the pixel circuit 433). As shown in FIG. 3, in each pixel, the APD 201 is arranged in the semiconductor layer 301, the pixel circuit 432 is arranged in the semiconductor layer 302, and the pixel circuit 433 is arranged in the semiconductor layer 303. The pixel circuit 433 is connected to the readout circuit 405 arranged in the semiconductor layer 303. The readout circuit 405 is connected to the memories 409 and 410 and the processing circuit 411, all of which are arranged in the semiconductor layer 304.

The APD 201 generates a charge pair corresponding to incident light by photoelectric conversion. A potential VL is supplied to the anode of the APD 201. A potential VH higher than the potential VL supplied to the anode is supplied to the cathode of the APD 201. A reverse bias voltage is supplied to the anode and the cathode so that the APD 201 performs an avalanche breakdown operation. In a state in which such a reverse bias voltage is supplied, charges generated by incident light cause avalanche breakdown, generating an avalanche current.

In a case where the reverse bias voltage is supplied to the APD 201, there are a Geiger mode in which the APD 201 is operated by a potential difference (voltage) between the anode and the cathode larger than a breakdown voltage, and a linear mode in which the APD 201 is operated by a potential difference between the anode and the cathode around the breakdown voltage or equal to or lower than the breakdown voltage. An APD operated in the Geiger mode is called a Single Photon Avalanche Diode (SPAD). For example, the potential VL is-30 V, and the potential VH is 1 V. The APD 201 may be operated in the linear mode or the Geiger mode.

A quench circuit 202 and a level shift circuit 220 are arranged as the pixel circuit 432 in the semiconductor layer 302. The quench circuit 202 is connected between the APD 201 and a power supply that supplies the potential VH. The quench circuit 202 functions as a load circuit at the time of signal multiplication by avalanche breakdown, and operates to suppress a voltage supplied to the APD 201 and suppress avalanche breakdown (quench operation). The quench circuit 202 also operates to return the voltage supplied to the APD 201 to a voltage (VH−VL) by supplying a current by an amount corresponding to a voltage drop caused by the quench operation (recharge operation).

The level shift circuit 220 shapes a potential change of the cathode of the APD 201 obtained at the time of photon detection to a signal that can be detected by the pixel circuit 433 of the succeeding stage. For example, the level shift circuit 220 outputs a pulse signal corresponding to the potential change of the APD 201. As the level shift circuit 220, for example, an inverter circuit may be used. However, the present invention is not limited to this, and another circuit may be used as the level shift circuit 220 as long as the circuit can shape the potential change of the cathode of the APD 201 obtained at the time of photon detection to a signal that can be detected by the pixel circuit 433.

A counter circuit or the like can be arranged as the pixel circuit 433 in the semiconductor layer 303. The counter circuit counts pulse signals output from the level shift circuit 220 and holds the count value. Furthermore, a selection circuit that switches electrical connection/disconnection between the counter circuit and a signal line 263 for outputting a signal to the readout circuit 405 may be arranged as the pixel circuit 433. The selection circuit can include, for example, a buffer circuit for outputting a signal. In addition, a reset circuit for resetting the count value counted by the counter circuit or the like may be arranged as the pixel circuit 433 in the semiconductor layer 303.

In this embodiment, the counter circuit is arranged as the pixel circuit 433. However, the present invention is not limited to this. For example, a Time-to-Digital Converter (TDC) and a memory may be arranged as the pixel circuit 433 instead of the counter circuit so that the photoelectric conversion apparatus 100 obtains a pulse detection timing. In this case, the generation timing of a pulse signal output from the level shift circuit 220 is converted into a digital signal by the TDC. The TDC is supplied with a reference signal for measurement of the timing of the pulse signal. By using the reference signal as a reference, the TDC obtains, as a digital signal, a signal when the input timing of a signal indicating the potential change of the APD 201 via the level shift circuit 220 is regarded as a relative time.

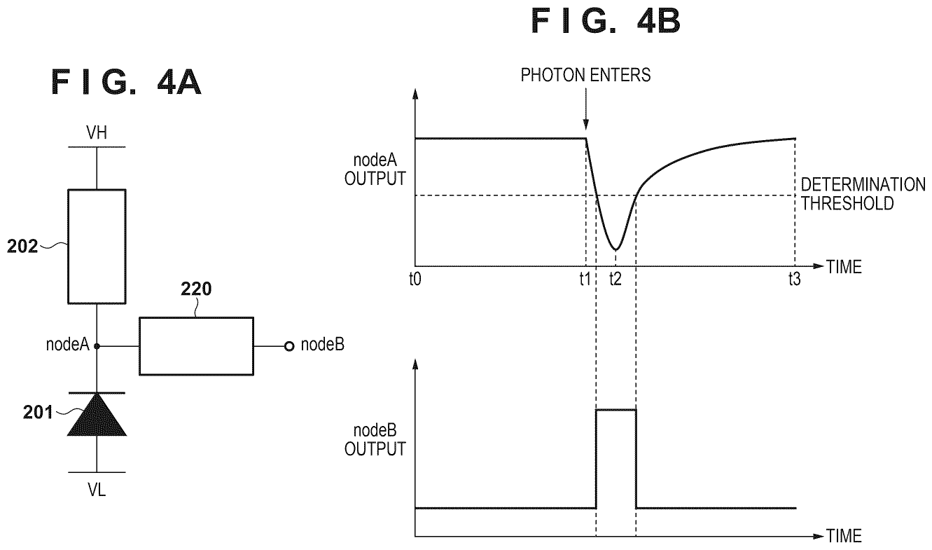

FIGS. 4A and 4B show a circuit diagram and timing charts schematically showing the relationship between the operation of the APD 201 and the output signal. FIG. 4A is a circuit diagram showing an excerpt of the APD 201, the quench circuit 202, and the level shift circuit 220 shown in FIG. 3. The input side of the level shift circuit 220 is a node A and the output side of the level shift circuit 220 is a node B. FIG. 4B shows waveform changes at the node A and the node B.

From time t0 to time t1, a potential difference (voltage) of the potential VH−the potential VL is applied to the APD 201. When a photon enters the APD 201 at time t1, avalanche breakdown occurs in the APD 201, an avalanche breakdown current flows into the quench circuit 202, and the potential of the node A drops. When the voltage drop amount further increases and the potential difference applied to the APD 201 decreases, the avalanche breakdown of the APD 201 stops as shown at time t2, and the potential level of the node A does not drop any more from a predetermined value. After that, in a period from time t2 to time t3, a current compensating for the voltage drop from the potential VL flows to the node A. At time t3, the node A is settled at the original potential level. At this time, a portion at which the output waveform exceeds a given threshold at the node A is waveform-shaped by the level shift circuit 220 and output as a signal to the node B.

The photoelectric conversion apparatus 100 is demanded to miniaturize the pixel, increase the number of pixels, achieve integration, and improve functionality. The photoelectric conversion apparatus 100 according to this embodiment stacks the four semiconductor layers 301 to 304. Among the APD 201, the pixel circuit 432, and the pixel circuit 433 forming one pixel, the APD 201 is arranged in the semiconductor layer 301, the pixel circuit 432 is arranged in the semiconductor layer 302, and the pixel circuit 433 is arranged in the semiconductor layer 303. This can decrease the number of components of one pixel and reduce its size in the semiconductor layers 301 to 303. As a result, miniaturization of the pixel is possible. In addition, since each pixel can be made small, a larger number of pixels can be obtained.

Furthermore, no pixel circuit forming the pixel is arranged in the semiconductor layer 304. Therefore, it is possible to provide a large area to the memories 409 and 410 and the processing circuit 411 for processing the signal output from the pixel. That is, it is possible to execute complicated processing of performing more calculation operations. That is, the functionality of the photoelectric conversion apparatus 100 can be improved.

The signals from the pixels distributed and arranged in the semiconductor layers 301 to 303 are stored as, for example, image data in the memories 409 and 410. The processing circuit 411 may execute various signal processes for the image data read out from the memory 409 or 410. For example, if the image data to be processed is color image data, the processing circuit 411 may convert the format into YUV image data or RGB image data, and output it via the output unit 412. Furthermore, for example, the processing circuit 411 may execute processing such as noise removal and white balance adjustment for the image data read out from the memory 409 or 410, as needed.

For example, image data of even-numbered frames are stored in the memory 409 and image data of odd-numbered frames are stored in the memory 410. While the storage operation of the image data in the memory 409 (or the memory 410) is performed, the processing circuit 411 may read out the image data from the memory 410 (or the memory 409) and perform processing. That is, the memories 409 and 410 may be frame memories. Furthermore, for example, the processing circuit 411 may process the image data written in the memory 409, and the processed image data may be stored in the memory 410. The processing circuit 411 may execute calculation processing using the image data based on the signals output from the pixels and the processed image data based on the signals obtained by processing the signals output from the pixels. Therefore, in consideration of the flow of the signals, the processing circuit 411 may be arranged between the memories 409 and 410, as shown in FIG. 2D.

If the TDC is arranged as the pixel circuit 433 and the photoelectric conversion apparatus 100 is used as a distance measurement device, the processing circuit 411 can also function as a distance measurement processing unit. For example, the processing circuit 411 may create a histogram based on information obtained from the TDC, and perform distance measurement calculation. The histogram is represented such that the abscissa represents a class (bin) related to the time and the ordinate represents a frequency at each class. The frequency indicates the number of times light is received during a predetermined light-receiving time. A count based on reflected light and ambient light is mixed in the histogram. Thus, by setting a predetermined threshold, the count of the reflected light component and the count of the ambient light component are separated. The distance between the distance measurement device and a measurement target object is calculated from a light arrival time corresponding to the reflected light component.

Furthermore, the processing circuit 411 may execute a program stored in the memory 409 or 410, thereby executing various processes using a learned model created by machine learning. For example, the learned model is created by machine learning using a deep neural network (DNN). The learned model is also called a neural network calculation model.

The learned model may be designed based on a parameter generated by inputting the signal output from the pixel and learning data linked with a label corresponding to the signal output from the pixel to a predetermined machine learning model. The predetermined machine learning model may be a learning model using a multilayer neural network. This learned model is also called a multilayer neural network model.

For example, the processing circuit 411 executes calculation processing based on the learned model stored in the memory 409 or 410. The calculation result is output to the memory 409 or 410 or the like. The calculation result includes image data obtained by executing the calculation processing using the learned model and various kinds of information (metadata) obtained from the image data.

The image data to be processed by the processing circuit 411 may be image data normally read out from the pixel, or image data whose data size is reduced by thinning out some data from the image data. The image data to be processed by the processing circuit 411 may be three-dimensional distance image data. With the three-dimensional distance image data, it is possible to accurately recognize an object and acquire accurate position information of the object since the information amount of the three-dimensional distance image data is larger than that of two-dimensional image data.

As described above, in the semiconductor layer 304, an area where the processing circuit 411 is arranged can be made large. Therefore, it is possible to mount the learned model for performing calculation with a heavy load, and execute processing of three-dimensional distance information data. This improves the functionality and performance of the photoelectric conversion apparatus 100.

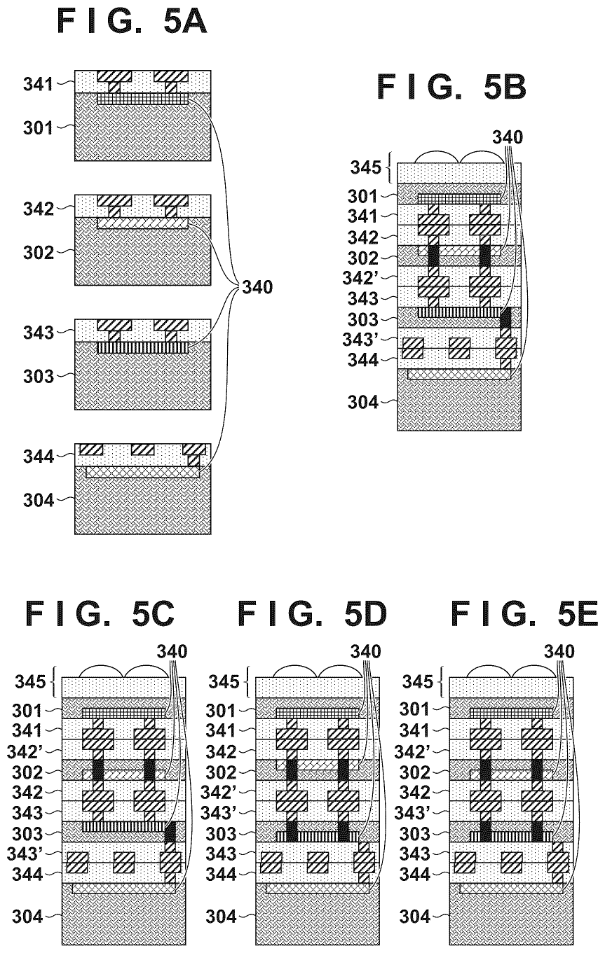

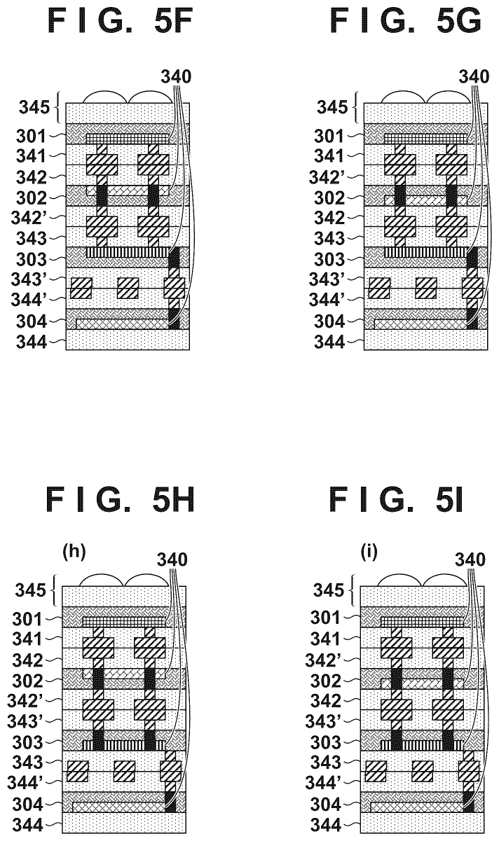

Consider the stacked structure of the photoelectric conversion apparatus 100 according to this embodiment. FIGS. 5A to 5I are views for explaining the arrangement of surfaces on which transistors and the like forming the above-described pixel circuits 432 and 433 and processing circuit 411 are arranged in the semiconductor layers 301 to 304. FIG. 5A shows the semiconductor layers 301 to 304, semiconductor device forming regions 340 formed in the semiconductor layers 301 to 304, and wiring layers 341 to 344 such as wiring patterns connected to the semiconductor devices arranged in the forming regions 340. In this embodiment, the photoelectric conversion apparatus 100 is a back-illuminated type photoelectric conversion apparatus, as shown in FIGS. 5B to 5I. Therefore, the APD 201 is connected to the wiring pattern arranged in the wiring layer 341 arranged on the opposite side of an optical layer 345 including a microlens on the light incident side of the photoelectric conversion apparatus 100.

Next, consider the directions of the semiconductor device forming regions 340 arranged in the semiconductor layers 302 to 304. In the following description, the light incident side of the photoelectric conversion apparatus 100 on which the optical layer 345 is arranged is set as the “upper side”. Therefore, for example, the semiconductor layer 302 is arranged on the “upper side” of the semiconductor layer 303, and is arranged on the “lower side” of the semiconductor layer 301. In the configuration shown in FIG. 5B, the semiconductor device forming region 340 in each of the semiconductor layers 302 to 304 faces upward. In the configuration shown in FIG. 5C, the semiconductor device forming region 340 in the semiconductor layer 302 faces downward, and the semiconductor device forming regions 340 in the semiconductor layers 303 and 304 face upward. In the configuration shown in FIG. 5D, the semiconductor device forming regions 340 in the semiconductor layers 302 and 304 face upward, and the semiconductor device forming region 340 in the semiconductor layer 303 faces downward. In the configuration shown in FIG. 5E, the semiconductor device forming regions 340 in the semiconductor layers 302 and 303 face downward, and the semiconductor device forming region 340 in the semiconductor layer 304 faces upward. In the configuration shown in FIG. 5F, the semiconductor device forming regions 340 in the semiconductor layers 302 and 303 face upward, and the semiconductor device forming region 340 in the semiconductor layer 304 faces downward. In the configuration shown in FIG. 5G, the semiconductor device forming regions 340 in the semiconductor layers 302 and 304 face downward, and the semiconductor device forming region 340 in the semiconductor layer 303 faces upward. In the configuration shown in FIG. 5H, the semiconductor device forming region 340 in the semiconductor layer 302 faces upward, and the semiconductor device forming regions 340 in the semiconductor layers 303 and 304 face downward. In the configuration shown in FIG. 5I, the semiconductor device forming region 340 in each of the semiconductor layers 302 to 304 faces downward.

As described above, the APD 201 arranged in the semiconductor layer 301 and the pixel circuit 432 arranged in the semiconductor layer 302 are in one-to-one correspondence with each other. The pixel circuit 432 arranged in the semiconductor layer 302 and the pixel circuit 433 arranged in the semiconductor layer 303 are in one-to-one correspondence with each other. The pixel circuit 432 is arranged in the semiconductor device forming region 340 in the semiconductor layer 302. Similarly, the pixel circuit 433 is arranged in the semiconductor device forming region 340 in the semiconductor layer 303. Therefore, in the pixel circuit array 402 of the semiconductor layer 302, through vias the number of which is equal to the number of pixels each formed by the APD 201 and the pixel circuits 432 and 433 are arranged regardless of the direction in which the semiconductor device forming region 340 in the semiconductor layer 302 is arranged.

Next, consider the direction of the semiconductor device forming region 340 in which the pixel circuit 433 and the like of the semiconductor layer 303 are arranged. As in the configuration shown in each of FIGS. 5D, 5E, 5H, and 5I, if the semiconductor device forming region 340 in the semiconductor layer 301 faces downward, through vias the number of which is equal to the number of pixels are necessary for the pixel circuit array 403 of the semiconductor layer 303. Since it is difficult to arrange semiconductor devices in a region where the through vias are arranged, this may be inappropriate for integration of the pixel circuits 433. On the other hand, as in the configuration shown in each of FIGS. 5B, 5C, 5F, and 5G, if the semiconductor device (pixel circuit 433) forming region 340 in the semiconductor layer 301 faces upward, it is unnecessary to form through vias in the pixel circuit array 403 of the semiconductor layer 303. Therefore, a case where the semiconductor device forming region 340 in the semiconductor layer 303 faces upward is more suitable for integration than in a case where the semiconductor device forming region 340 in the semiconductor layer 303 faces downward. That is, the semiconductor devices forming the pixel circuit 433 and the like may be arranged on the surface of the semiconductor layer 303 on the side of the semiconductor layer 302.

Following the direction of the semiconductor device forming region 340 in the semiconductor layer 303, consider the direction of the semiconductor device forming region 340 in which the processing circuit 411 and the memories 409 and 410 of the semiconductor layer 304 are arranged. As in the configuration shown in each of FIGS. 5F to 5I, if the semiconductor device forming region 340 in the semiconductor layer 301 faces downward, the parasitic capacitance of the wiring pattern for transferring the signal from the semiconductor layer 303 to the semiconductor layer 304 increases, thereby making it difficult to increase the speed. On the other hand, as in the configuration shown in each of FIGS. 5B to 5E, if the semiconductor device forming region 340 in the semiconductor layer 301 faces upward, the wiring pattern for connecting the semiconductor layers 303 and 304 becomes shorter than in a case where the semiconductor device forming region 340 in the semiconductor layer 301 faces downward. As a result, the parasitic capacitance of the wiring pattern for transferring the signal from the semiconductor layer 303 to the semiconductor layer 304 decreases, thereby making it easy to increase the speed. That is, the semiconductor devices forming the processing circuit 411 and the like may be arranged on the surface of the semiconductor layer 304 on the side of the semiconductor layer 303.

In consideration of the above description, as shown in FIGS. 5B and 5C, a case where the semiconductor device forming region 340 in each of the semiconductor layers 303 and 304 faces upward is more suitable for improving the performance of the photoelectric conversion apparatus 100.

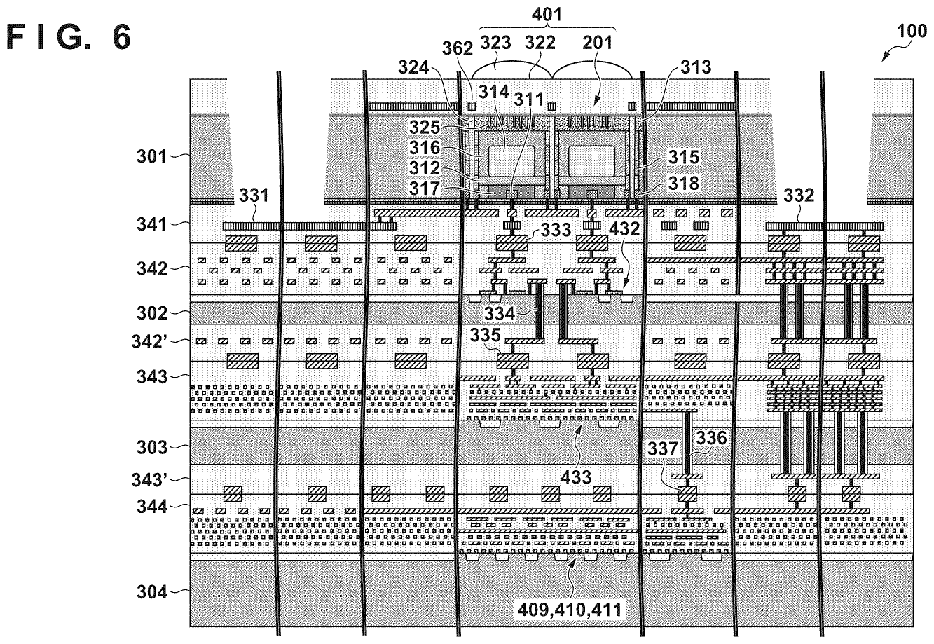

FIG. 6 is a sectional view showing the more detailed configuration of the photoelectric conversion apparatus 100 shown in FIG. 5B. The APD 201 is arranged in the semiconductor layer 301. The APD 201 includes semiconductor regions 311, 314, 316, and 317 of the same conductivity type. Furthermore, the APD 201 includes semiconductor regions 312, 313, 315, and 318 of a conductivity type opposite to that of the semiconductor regions 311, 314, 316, and 317. For example, the semiconductor regions 311, 314, 316, and 317 can be n-type semiconductor regions and the semiconductor regions 312, 313, 315, and 318 can be p-type semiconductor regions. An example of a semiconductor material used for the semiconductor layers 301 to 304 is silicon. Therefore, each of the semiconductor regions 311 to 318 can be a region where an impurity corresponding to the conductivity type is implanted into silicon. For example, each of the semiconductor regions 311 to 315, 317, and 318 may be formed in the n-type semiconductor layer 301 (semiconductor region 316) using an ion implantation method or the like.

The semiconductor region 311 is a region having a higher n-type impurity concentration than the semiconductor regions 314 and 317. A p-n junction portion is formed between the p-type semiconductor region 312 and the n-type semiconductor region 311. By setting the impurity concentration of the semiconductor region 312 lower than the impurity concentration of the semiconductor region 311, a reverse bias is applied and the whole region of the semiconductor region 312 overlapping the center of the semiconductor region 311 becomes a depletion layer region. In this case, the potential difference between the semiconductor regions 311 and 312 is larger than the potential difference between the semiconductor regions 312 and 314. Furthermore, the depletion layer region extends to a partial region of the semiconductor region 311, and a strong electric field is induced in the depletion layer region. This strong electric field induces avalanche breakdown in the depletion layer region extending to the partial region of the semiconductor region 311, and a current based on the multiplied charges is output as a signal charge. When the light having entered the APD 201 is photoelectrically converted and avalanche breakdown is induced in the depletion layer region (avalanche breakdown region), the generated n-type charges are collected in the semiconductor region 311.

The semiconductor region 311 is connected to the pixel circuit 432 arranged in the semiconductor layer 302 via the wiring patterns arranged in the wiring layers 341 and 342 and the connection portions 333. The semiconductor region 312 is connected to a pad electrode 331 via the semiconductor regions 315 and 318 and the wiring pattern arranged in the wiring layer 341. By setting the impurity concentration of the semiconductor region 318 higher than the impurity concentration of the semiconductor region 315, the contact resistance between the semiconductor region 318 and the wiring pattern is reduced. As shown in FIG. 6, the pad electrode 331 is exposed via an opening formed in the semiconductor layer 301 between the semiconductor layers 301 and 302. The pad electrode 331 is connected to the semiconductor region 312 to function as the anode of the APD 201. The pad electrode 331 may be shared by the plurality of APDs 201.

The APDs 201 are isolated by a trench structure 324 provided in the semiconductor layer 301. A scattering diffraction structure 325 may be provided in the APD 201. The scattering diffraction structure 325 can be formed by forming trenches in the surface of the semiconductor layer 301 on the light incident side and embedding an appropriate material in the trenches.

A microlens 323 (the above-described optical layer 345) may be arranged on the semiconductor layer 301 via an insulating layer 322. A light shielding portion 326 for reducing a crosstalk between the adjacent APDs 201 may be arranged in the insulating layer 322. In addition, a color filter and the like may be arranged on the semiconductor layer 301.

The pixel circuit 432 arranged in the semiconductor layer 302 and the pixel circuit 433 arranged in the semiconductor layer 303 are connected via through vias 334 provided in the semiconductor layer 302, the wiring patterns provided in a wiring layer 342′ and the wiring layer 343, and the connection portions 335. The pixel circuit 433 arranged in the semiconductor layer 303 and the memories 409 and 410 and the processing circuit 411 arranged in the semiconductor layer 304 are connected via through vias 336 provided in the semiconductor layer 303, the wiring patterns provided in a wiring layer 343′ and the wiring layer 344, and the connection portions 337.

As described above, the connection portion 333 is arranged to connect the APD 201 arranged in the semiconductor layer 301 and the pixel circuit 432 arranged in the semiconductor layer 302. Although a manufacturing method will be described later, the connection portion 333 is a metal pattern that connects the wiring layer 341 formed to cover the semiconductor layer 301 and the wiring layer 342 formed to cover the semiconductor layer 302. As shown in FIGS. 2A and 6, the connection portion 333 is arranged to overlap each APD 201. As described above, the connection portion 335 is arranged to connect the pixel circuit 432 arranged in the semiconductor layer 302 and the pixel circuit 433 arranged in the semiconductor layer 303. The connection portion 335 is a metal pattern that connects the wiring layer 342′ formed to cover the semiconductor layer 302 and the wiring layer 343 formed to cover the semiconductor layer 303. As shown in FIGS. 2B and 6, the connection portion 335 is arranged to overlap each pixel circuit 432. Each of the connection portions 333 and 335 is arranged to overlap the APD 201 and the pixel circuits 432 and 433 in the pixel formed by the APD 201 and the pixel circuits 432 and 433. Thus, miniaturization and integration of the pixels are implemented.

On the other hand, as shown in FIG. 6, the through vias 336 each for connecting the pixel circuit 433 arranged in the semiconductor layer 303 and the memories 409 and 410 and the processing circuit 411 arranged in the semiconductor layer 304 are arranged in a region not overlapping the APD array 401 in which the APDs 201 are arranged. If the through vias 336 extending through the semiconductor layer 303 are arranged in a region overlapping the APD array 401, a region necessary for not only the pixel circuits 433 but also the through vias 336 is necessary for the region overlapping the APD array 401. That is, it may be impossible to implement miniaturization of the pixel formed by the APD 201 and the pixel circuits 432 and 433. Therefore, the through vias 336 are arranged in a region not overlapping the APD array 401.

Furthermore, as described above, the connection portions 337 connected to the through vias 336 connect the signal transfer unit 406 arranged in the semiconductor layer 303 and the signal reception unit 407 arranged in the semiconductor layer 304. In other words, the connection portions 337 are arranged to connect the pixels each formed by the APD 201 and the pixel circuits 432 and 433 to the memories 409 and 410 and the processing circuit 411. The connection portion 337 is a metal pattern that connects the wiring layer 343′ formed to cover the semiconductor layer 303 and the wiring layer 344 formed to cover the semiconductor layer 304. Since the through vias 336 are arranged in a region not overlapping the APD array 401, as described above, the connection portions 337 can also be arranged in a region not overlapping the APD array 401 in which the APDs 201 are arranged, as shown in FIG. 6. Therefore, as shown in FIGS. 2C and 6, it can be said that the signal transfer unit 406 and the signal reception unit 407 are arranged in a region not overlapping the APD array 401 in which the APDs 201 are arranged.

In this example, as shown in FIG. 6, the semiconductor layer 302 may be thinner than the semiconductor layer 303. In the semiconductor layer 302, the through vias 334 the number of which is equal to the number of pixels each formed by the APD 201 and the pixel circuits 432 and 433 are formed. That is, the number of through vias 334 arranged in the semiconductor layer 302 may be larger than the number of through vias 334 arranged in the semiconductor layer 303. Therefore, the semiconductor layer 302 may be thinner than the semiconductor layer 303 in consideration of the manufacturing step of the photoelectric conversion apparatus. By thinning the semiconductor layer 302, the speed can be increased by improving the degree of integration of the pixels and reducing the parasitic capacitance in the through vias 334.

The semiconductor layer 303 may be thinner than the semiconductor layer 304. This is because the through vias 336 are formed in the semiconductor layer 303 but no through via is formed in the semiconductor layer 304, as shown in FIG. 6. By thinning the semiconductor layer 303, the speed can be increased by improving the degree of integration of the pixels and reducing the parasitic capacitance in the through vias 336. For example, the semiconductor layer 302 may be thinned to 1 μm or less. The semiconductor layer 303 may have a thickness of, for example, about 1 μm to 10 μm. On the other hand, the semiconductor layer 304 may have a thickness of, for example, about 50 μm to 100 μm. Furthermore, the semiconductor layer 304 need not be thinned to have a thickness of 725 μm or 775 μm. Furthermore, the semiconductor layer 301 may change in accordance with the wavelength of detected light and the like, and may have a thickness of, for example, about 2 μm to 10 μm.

As shown in FIG. 6, the photoelectric conversion apparatus 100 may include one pad electrode 332 for supplying a common potential to the semiconductor layers 303 and 304. The common potential may be a ground potential. The APD 201 and the pixel circuits 432 and 433 arranged in the semiconductor layers 301 to 303 can operate in accordance with a signal output from the scanning circuit 404 arranged in the semiconductor layer 303. Thus, by supplying the common potential to the semiconductor layers 303 and 304, a variation in power supply potential in each of the semiconductor layers 301 to 304 is suppressed, and for example, the output of the signal from the pixel is stabilized.

Furthermore, the width of the through via 336 extending through the semiconductor layer 303 may be larger than the width of the through via 334 extending through the semiconductor layer 302. The width of the through via 334 or 336 may be the width of a thinnest portion of the through via 334 or 336 in a portion extending through the semiconductor layer 303 or 302, in the sectional view shown in FIG. 6. The through via 334 is provided for each pixel formed by the APD 201 and the pixel circuits 432 and 433. It is difficult to arrange the pixel circuit 432 in the portion in which the through via 334 is arranged. To miniaturize the pixel and achieve integration, the through via 334 is formed to be smaller than the through via 336. On the other hand, the number of through vias 336 is smaller than the number of through vias 334, and the through vias 336 are arranged to overlap a region outside the APD array 401. Thus, by increasing the width of the through via 336, the resistance of the through via 336 is reduced, thereby improving the signal transfer ability from the pixel circuit 433 to the memories 409 and 410 and the processing circuit 411. This increases the speed of the photoelectric conversion apparatus 100.

As described above, the characteristic of the APD 201 may change along with a change of the temperature. On the other hand, the processing circuit 411 may execute calculation with a heavy load to improve the performance of the photoelectric conversion apparatus 100, thereby increasing the heat generation amount. To cope with this, thermal design that suppresses heat generated in the semiconductor layer 304 from being transferred to the semiconductor layer 301 is required. To do this, in a planar view, the total area of the through vias 336 provided in the semiconductor layer 303 may be smaller than the total area of the through vias 334 provided in the semiconductor layer 302. In consideration of the thermal design, in a planar view, the area of the through via 334 or 336 may be the area of a portion of the through via 334 or 336 whose section is smallest in a portion extending through the semiconductor layer 302 or 304.

For the through vias 334 and 336, a material having high thermal conductivity such as a metal can be used. Therefore, in a planar view, by making the total area of the through vias 336 smaller than the total area of the through vias 334, heat generated in the semiconductor layer 304 is difficult to be transferred to the semiconductor layer 301. The through via 336 can have a width larger than the width of the through via 334, as described above. However, since the number of through vias 336 is smaller than the number of through vias 334, the total area of the through vias 336 can be made small.

As described above, the through vias 336, the connection portions 337, the signal transfer unit 406, and the signal reception unit 407 are arranged in a region not overlapping the APD array 401. Thus, as compared to a case where the through vias 336, the connection portions 337, the signal transfer unit 406, and the signal reception unit 407 are arranged to overlap the APD array 401, it is possible to suppress heat transferred to the surface of the semiconductor layer 303 on the side of the semiconductor layer 302 from being transferred to the semiconductor layer 301. While these components that easily transfer heat from the semiconductor layer 304 to the semiconductor layer 303 are arranged not to overlap the APD array 401, the processing circuit 411 may be arranged to overlap the APD array 401, as shown in FIGS. 2A, 2D, and 6. This is because heat is mainly transferred from the semiconductor layer 304 to the semiconductor layer 303 via the through vias 336 and the connection portions 337.

Although not shown in FIG. 6, a phase synchronization circuit (phase locked loop (PLL) circuit) for controlling the operation timing of the overall photoelectric conversion apparatus 100 may be arranged in the semiconductor layer 304. In the semiconductor layer 304, a clock signal for controlling the overall photoelectric conversion apparatus 100 is generated and supplied to the semiconductor layers 301 to 304. A frequency divider circuit and the like may be arranged in the semiconductor layers 301 to 303. For example, a phase synchronization circuit (PLL circuit) may be arranged in each of the semiconductor layers 303 and 304. One of the phase synchronization circuit arranged in the semiconductor layer 303 and the phase synchronization circuit arranged in the semiconductor layer 304 sends an original signal to the other, thereby generating a clock signal. The phase synchronization circuit arranged in the semiconductor layer 303 may generate a clock signal for controlling the respective components of the semiconductor layers 301 to 303, and the phase synchronization circuit arranged in the semiconductor layer 304 generate a clock signal for controlling the respective components of the semiconductor layer 304.

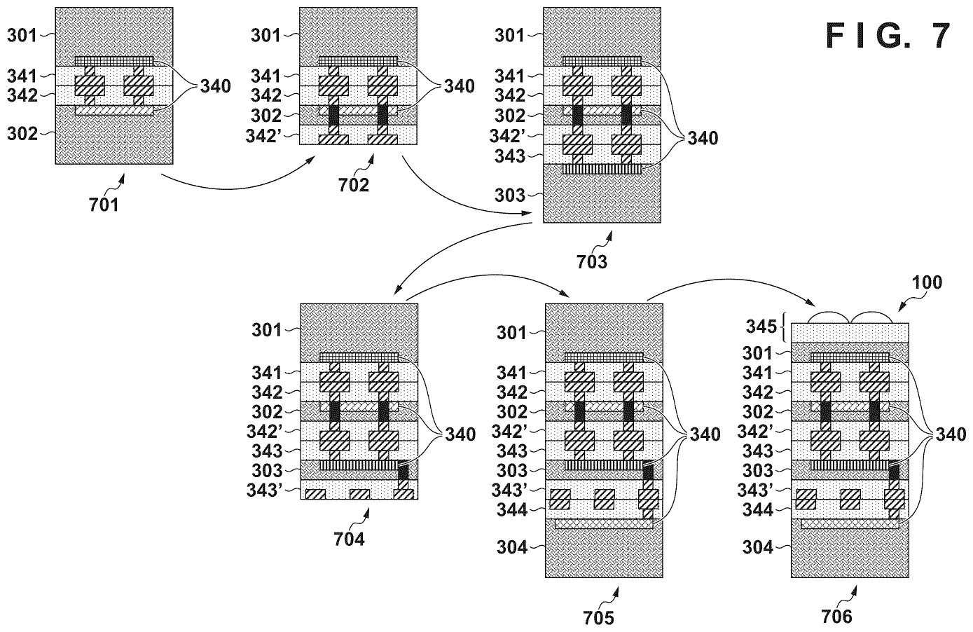

A manufacturing method of the photoelectric conversion apparatus 100 shown in FIGS. 5B and 6 will be described next with reference to FIG. 7. First, the semiconductor layers 301 to 304 respectively including the wiring layers 341 to 344 are prepared, as shown in FIG. 5A. More specifically, the APDs 201 are formed in the semiconductor layer 301, and the wiring layer 341 is formed to cover the semiconductor device forming region 340 in which the APDs 201 are arranged. The pixel circuits 432 and the like are formed in the semiconductor layer 302, and the wiring layer 342 is formed to cover the semiconductor device forming region 340 in which the pixel circuits 432 are arranged. The pixel circuits 433 and the like are formed in the semiconductor layer 303, and the wiring layer 343 is formed to cover the semiconductor device forming region 340 in which the pixel circuits 433 are arranged. The memories 409 and 410, the processing circuit 411, and the like are formed in the semiconductor layer 304, and the wiring layer 344 is formed to cover the semiconductor device forming region 340 in which the memories 409 and 410 and the processing circuit 411 are arranged. The semiconductor layers 301 to 304 respectively including the wiring layers 341 to 344 may be manufactured in parallel or in an appropriate order. In each step shown in FIG. 7, the necessary semiconductor layers 301 to 304 respectively including the wiring layers 341 to 344 need only be usable.

Next, as shown in a step 701, the semiconductor layers 301 and 302 are bonded via the wiring layers 341 and 342. The metal pattern arranged on the outermost surface of the wiring layer 341 and the metal pattern arranged on the outermost surface of the wiring layer 342 are bonded to form the above-described connection portions 333.

After the semiconductor layers 301 and 302 are bonded, the semiconductor layer 302 is thinned from the opposite side of the semiconductor layer 301 and the through vias 334 and the like are formed in the semiconductor layer 302, as shown in a step 702. Furthermore, the wiring layer 342′ is formed to cover the surface of the semiconductor layer 302 on the opposite side of the semiconductor layer 301 (the surface on the opposite side of the semiconductor device forming region 340).

Next, as shown in a step 703, the semiconductor layers 302 and 303 are bonded via the wiring layers 342′ and 343. The metal pattern arranged on the outermost surface of the wiring layer 342′ and the metal pattern arranged on the outermost surface of the wiring layer 343 are bonded to form the above-described connection portions 335.

After the semiconductor layers 302 and 303 are bonded, the semiconductor layer 303 is thinned from the opposite side of the semiconductor layer 302 and the through vias 336 and the like are formed in the semiconductor layer 303, as shown in a step 704. Furthermore, the wiring layer 343′ is formed to cover the surface of the semiconductor layer 303 on the opposite side of the semiconductor layer 302 (the surface on the opposite side of the semiconductor device forming region 340).

Next, as shown in a step 705, the semiconductor layers 303 and 304 are bonded via the wiring layers 343′ and 344. The metal pattern arranged on the outermost surface of the wiring layer 343′ and the metal pattern arranged on the outermost surface of the wiring layer 344 are bonded to form the above-described connection portions 337.

After the semiconductor layers 303 and 304 are bonded, the semiconductor layer 301 is thinned from the opposite side of the semiconductor layer 302, as shown in a step 706. Next, the optical layer 345 such as a microlens is formed on the surface of the semiconductor layer 301 on the opposite side of the semiconductor layer 302 (the surface on the light incident side of the semiconductor layer 301), thereby manufacturing the photoelectric conversion apparatus 100 shown in FIGS. 5B and 6.

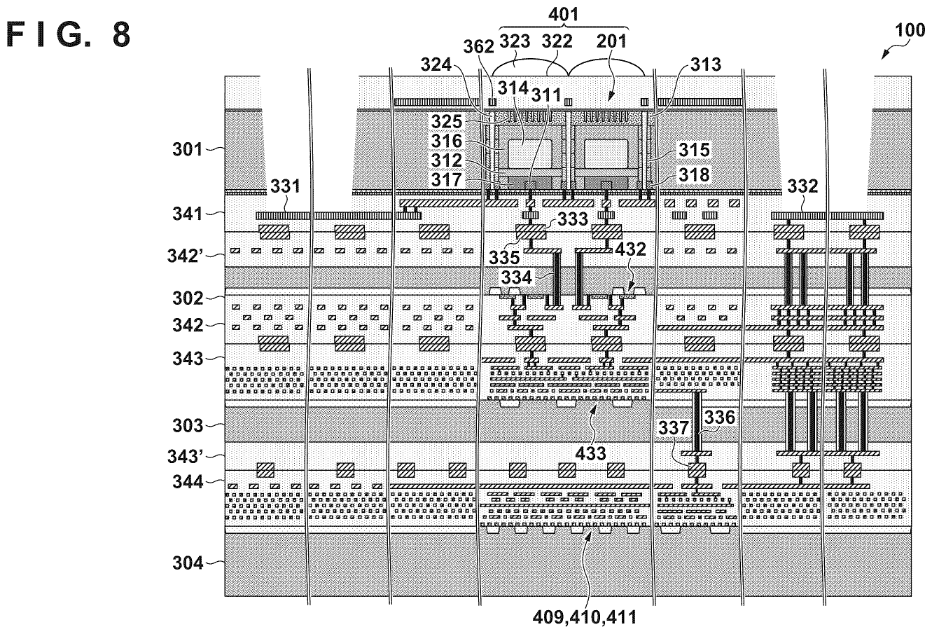

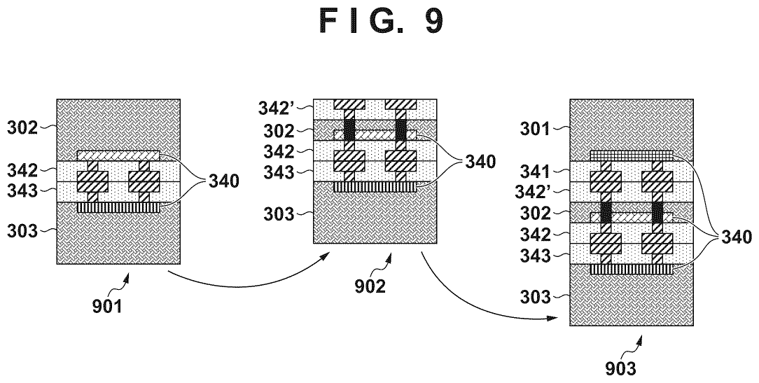

FIG. 8 is a sectional view showing the more detailed configuration of the photoelectric conversion apparatus 100 shown in FIG. 5C. In the configuration shown in FIGS. 5B and 6, in the semiconductor layer 302, the semiconductor device forming region 340 in which the pixel circuits 432 and the like are arranged is arranged on the side of the semiconductor layer 301. On the other hand, in the configuration shown in FIGS. 5C and 8, in the semiconductor layer 302, the semiconductor device forming region 340 in which the pixel circuits 432 and the like are arranged is arranged on the side of the semiconductor layer 303. The remaining components are the same as those described with reference to FIG. 6 and a description thereof will be omitted.

A manufacturing method of the photoelectric conversion apparatus 100 shown in FIGS. 5C and 8 will be described next with reference to FIG. 9. First, as described above, the semiconductor layers 301 to 304 respectively including the wiring layers 341 to 344 are prepared, as shown in FIG. 5A. Next, as shown in a step 901, the semiconductor layers 302 and 303 are bonded via the wiring layers 342 and 343. The metal pattern arranged on the outermost surface of the wiring layer 342 and the metal pattern arranged on the outermost surface of the wiring layer 343 are bonded to form the above-described connection portions 335.

After the semiconductor layers 302 and 303 are bonded, the semiconductor layer 302 is thinned from the opposite side of the semiconductor layer 303 and the through vias 334 and the like are formed in the semiconductor layer 302, as shown in a step 902. Furthermore, the wiring layer 342′ is formed to cover the surface of the semiconductor layer 302 on the opposite side of the semiconductor layer 303 (the surface on the opposite side of the semiconductor device forming region 340).

Next, as shown in a step 903, the semiconductor layers 301 and 302 are bonded via the wiring layers 341 and 342′. The metal pattern arranged on the outermost surface of the wiring layer 341 and the metal pattern arranged on the outermost surface of the wiring layer 342′ are bonded to form the above-described connection portions 333.

Steps after the semiconductor layers 301 and 302 are bonded and the semiconductor layers 301 to 303 are stacked may be the same as the steps 704 to 706 shown in FIG. 7. Therefore, a description thereof will be omitted. By using these steps, the photoelectric conversion apparatus 100 shown in FIGS. 5C and 8 is manufactured.

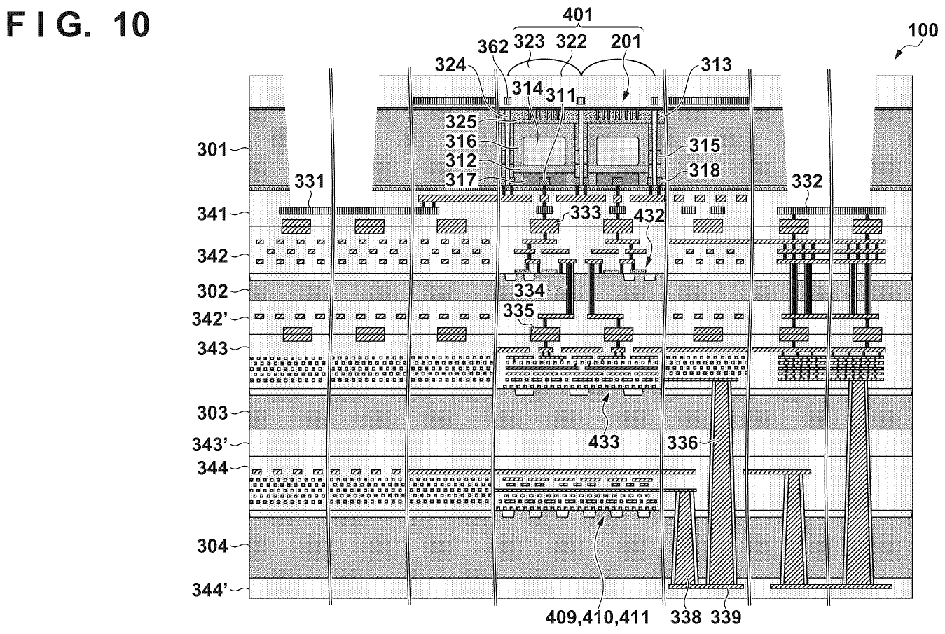

FIG. 10 is a sectional view showing a modification of the photoelectric conversion apparatus 100 shown in FIG. 6. In the photoelectric conversion apparatus 100 shown in FIG. 10, a configuration for connecting the pixel circuit 433 arranged in the semiconductor layer 303 to the memories 409 and 410 and the processing circuit 411 arranged in the semiconductor layer 304 is different from the configuration shown in FIG. 6. In the configuration shown in FIG. 6, the semiconductor layers 303 and 304 are connected via the through vias 336 provided in the semiconductor layer 303, the wiring patterns provided in the wiring layers 343 and 344, and the connection portions 337. On the other hand, in the configuration shown in FIG. 10, the through vias 336 extend through not only the semiconductor layer 303 but also the semiconductor layer 304 and are connected to connection portions 339 (to be also referred to as a wiring pattern hereinafter) provided in a wiring layer 344′ that covers the surface of the semiconductor layer 304 on the opposite side of the semiconductor layer 303. Furthermore, the memories 409 and 410, the processing circuit 411, and the like arranged in the semiconductor layer 304 are connected to the connection portions 339 via the wiring pattern arranged in the wiring layer 344 and through vias 338 extending through the semiconductor layer 304. That is, the semiconductor layers 303 and 304 are connected via the through vias 336 provided in the semiconductor layers 303 and 304, the connection portions 339 provided in the wiring layer 344′, the through vias 338 provided in the semiconductor layer 304, and the wiring pattern provided in the wiring layer 344. By connecting the semiconductor layers 303 and 304 in the semiconductor layer 304 on the opposite side of the semiconductor layer 303, heat generated in the semiconductor layer 304 is difficult to be transferred to the semiconductor layer 301. The remaining components may be the same as those described with reference to FIG. 6 and a description thereof will be omitted.

In the configuration shown in FIG. 10 as well, the width of the through via 336 extending through the semiconductor layer 303 may be larger than the width of the through via 334 extending through the semiconductor layer 302. In a planar view, the total area of the through vias 336 provided in the semiconductor layer 303 may be smaller than the total area of the through vias 334 provided in the semiconductor layer 302.

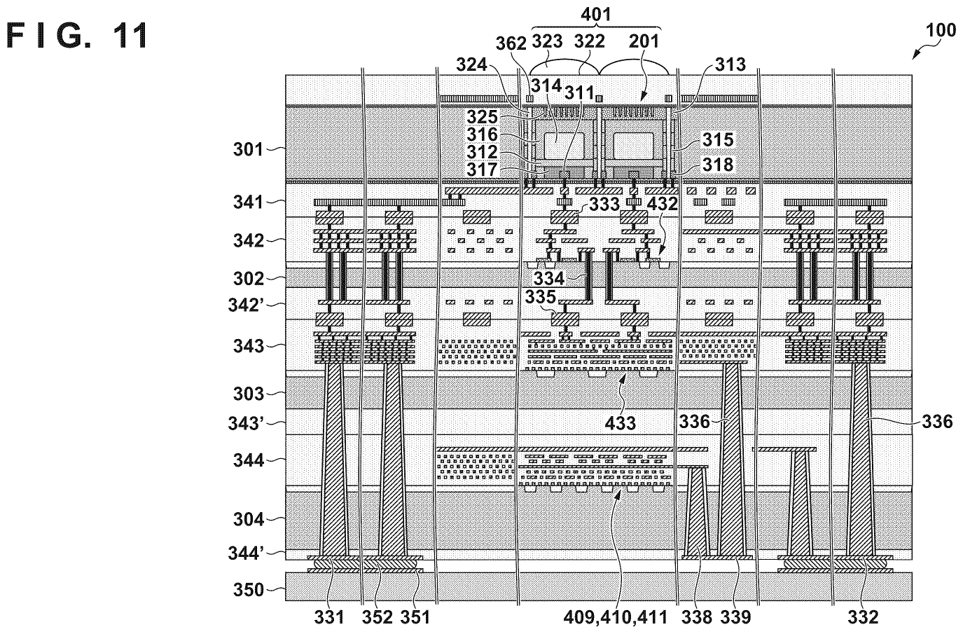

FIG. 11 is a sectional view showing a modification of the photoelectric conversion apparatus 100 shown in FIG. 10. In the configuration shown in each of FIGS. 6, 8, and 10, the pad electrodes 331 and 332 are exposed via openings formed in the semiconductor layer 301. That is, each of the pad electrodes 331 and 332 is configured to be connectable from the light incident side of the photoelectric conversion apparatus 100 using a conductive wire or the like. On the other hand, in the configuration shown in FIG. 11, the pad electrodes 331 and 332 are arranged on the surface of the wiring layer 344′ on the opposite side of the light incident side of the photoelectric conversion apparatus 100. Therefore, the semiconductor region 312 in which the APDs 201 are formed is connected to the pad electrode 331 via the semiconductor regions 315 and 318, the wiring patterns arranged in the wiring layers 341, 342, 342′, and 343, and the through vias 334 and 336. The pad electrode 332 for supplying the common potential to the semiconductor layers 303 and 304 is directly or indirectly connected to the pixel circuit 433, the memories 409 and 410, the processing circuit 411, and the like arranged in the semiconductor layers 303 and 304 via the through vias 336 and 338. As shown in, for example, FIG. 11, each of the pad electrodes 331 and 332 is connected to an electrode 351 of a wiring board 350 or an external apparatus of the photoelectric conversion apparatus 100 via a conductive member 352 such as a solder. This implements connection to an apparatus arranged outside the photoelectric conversion apparatus 100. The pad electrodes 331 and 332 may be formed in a layer that is the same as or different from the layer of the above-described connection portions 339 in the wiring layer 344′, as shown in FIG. 11. The remaining components may be the same as those described with reference to FIG. 6 and a description thereof will be omitted.

In the configuration shown in each of FIGS. 10 and 11, the pixel circuit 432 is arranged in the semiconductor layer 302 on the side of the semiconductor layer 301. However, the present invention is not limited to this, and the pixel circuit 432 may be arranged in the semiconductor layer 302 on the side of the semiconductor layer 303, similar to the configuration shown in FIGS. 5C and 8.

An application example of the above-described photoelectric conversion apparatus 100 will be described below.

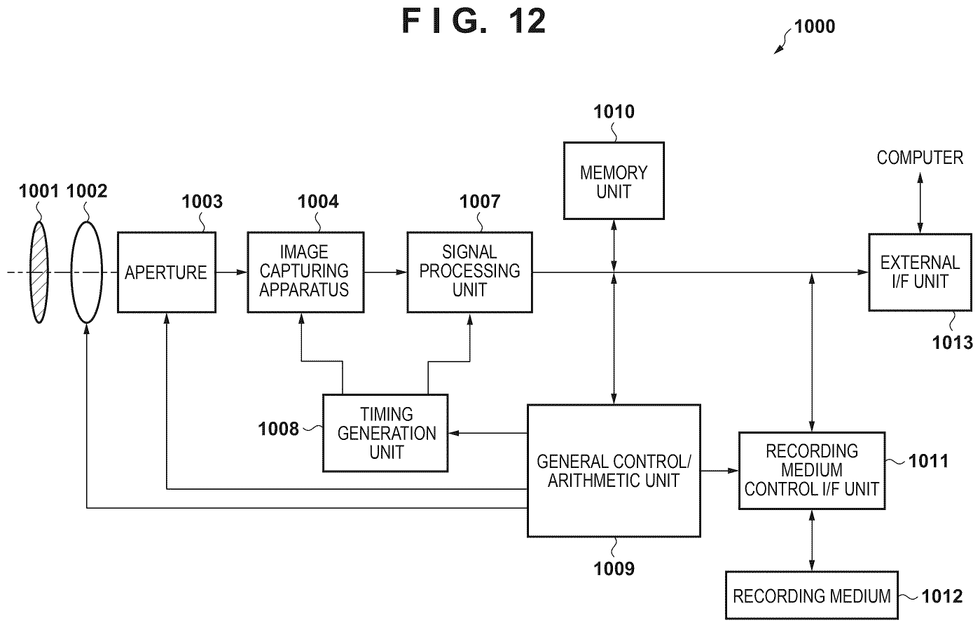

FIG. 12 is a block diagram showing the schematic configuration of a photoelectric conversion system. The photoelectric conversion apparatus 100 described in each of the above-described embodiments is applicable to various kinds of photoelectric conversion systems. Examples of photoelectric conversion systems to which the photoelectric conversion apparatus is applicable are a digital still camera, a digital camcorder, a monitoring camera, a copying machine, a facsimile apparatus, a mobile phone, an in-vehicle camera, and an observation satellite. A camera module including an optical system such as a lens and an image capturing apparatus is also included in the photoelectric conversion systems. FIG. 12 exemplarily shows the block diagram of a digital still camera as an example of these.

A photoelectric conversion system 1000 exemplarily shown in FIG. 12 includes an image capturing apparatus 1004 as an example of the photoelectric conversion apparatus, a lens 1002 that forms an optical image of an object on the image capturing apparatus 1004, an aperture 1003 configured to change the amount of light passing through the lens 1002, and a barrier 1001 configured to protect the lens 1002. The lens 1002 and the aperture 1003 form an optical system (optical apparatus) that condenses light to the image capturing apparatus 1004. The image capturing apparatus 1004 is the photoelectric conversion apparatus 100 (image capturing apparatus) according to one of the above-described embodiments, and converts the optical image formed by the lens 1002 into an electrical signal.

The photoelectric conversion system 1000 also includes a signal processing unit 1007 that is an image generation unit configured to generate an image by processing an output signal output from the image capturing apparatus 1004. The signal processing unit 1007 functions as a processing apparatus that performs an operation of performing various kinds of correction and compression as needed, thereby outputting image data. The signal processing unit 1007 may be formed on a semiconductor substrate on which the image capturing apparatus 1004 is provided or may be formed on a semiconductor substrate different from the image capturing apparatus 1004. In addition, the image capturing apparatus 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control interface unit (recording medium control I/F unit) 1011 configured to perform record or readout for the recording medium 1012. The recording medium control I/F unit 1011 and the recording medium 1012 can form a part of a recording apparatus. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1008 that outputs various kinds of timing signals to the image capturing apparatus 1004 and the signal processing unit 1007. The general control/arithmetic unit 1009 and the timing generation unit 1008 can form a part of a control apparatus configured to control an operation of the photoelectric conversion system 1000. In this example, the timing signal and the like may be input from the outside, and the photoelectric conversion system 1000 need only include at least the image capturing apparatus 1004, and the signal processing unit 1007 that processes an output signal output from the image capturing apparatus 1004.

The image capturing apparatus 1004 outputs an image capturing signal to the signal processing unit 1007. The signal processing unit 1007 executes predetermined signal processing for the image capturing signal output from the image capturing apparatus 1004, and outputs image data. The signal processing unit 1007 generates an image using the image capturing signal. Although not shown in FIG. 12, a display apparatus such as a display for displaying the generated image may be arranged in the photoelectric conversion system 1000. As described above, according to this embodiment, it is possible to implement the photoelectric conversion system 1000 to which the photoelectric conversion apparatus 100 (image capturing apparatus) according to one of the above-described embodiments is applied.

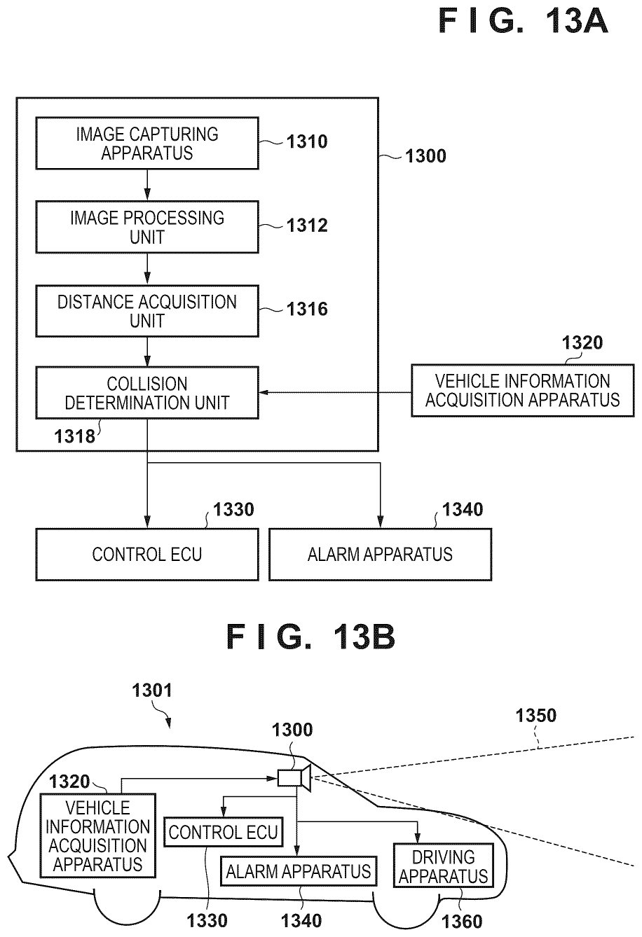

FIGS. 13A and 13B are views showing the configurations of a photoelectric conversion system 1300 and a moving body 1301, respectively. FIG. 13A shows an example of a photoelectric conversion system concerning an in-vehicle camera. The photoelectric conversion system 1300 includes an image capturing apparatus 1310. The image capturing apparatus 1310 is the photoelectric conversion apparatus 100 (image capturing apparatus) described in one of the above-described embodiments. The photoelectric conversion system 1300 includes an image processing unit 1312 that performs image processing for a plurality of image data acquired by the image capturing apparatus 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using a Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), an Application Specific Integrated Circuit (ASIC), or the like, or may be implemented by a combination of these.

The photoelectric conversion system 1300 is connected to a vehicle information acquisition apparatus 1320, and can acquire vehicle information such as a vehicle speed, a yaw rate, and a steering angle. The photoelectric conversion system 1300 is also connected to an ECU 1330 that is a control apparatus configured to output a control signal for generating a braking force to the vehicle based on the determination result of the collision determination unit 1318. Furthermore, the photoelectric conversion system 1300 is connected to an alarm apparatus 1340 that generates an alarm to the driver based on the determination result of the collision determination unit 1318. For example, if collision possibility is high as the determination result of the collision determination unit 1318, the ECU 1330 controls a driving apparatus (mechanical apparatus) 1360 to perform braking, releasing the accelerator pedal, or suppressing the engine output, thereby controlling the vehicle for avoiding collision and reducing damage. The alarm apparatus 1340 sounds an alarm, displays alarm information on the screen of a car navigation system or the like, or applies a vibration to the seat belt or a steering wheel, thereby making an alarm to the user.

In this embodiment, the periphery of the vehicle (moving body 1301), for example, the front or rear side is captured by the photoelectric conversion system 1300. FIG. 13B shows the photoelectric conversion system when capturing the front side (image capturing range 1350) of the vehicle. The vehicle information acquisition apparatus 1320 sends an instruction to the photoelectric conversion system 1300 or the image capturing apparatus 1310. With this configuration, it is possible to further improve the accuracy of distance measurement.

An example in which control is executed so as not to collide with another vehicle has been explained above. The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving apparatus) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller, or the like. In addition, the photoelectric conversion system can be applied not only to a moving body but also to equipment that broadly uses object recognition, such as an intelligent transport system (ITS).

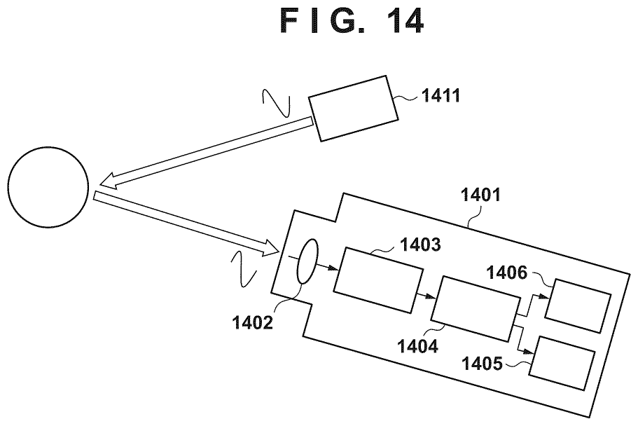

FIG. 14 is a block diagram showing an example of the configuration of a distance image sensor 1401 as the photoelectric conversion system. As shown in FIG. 14, the distance image sensor 1401 includes an optical system 1402, a photoelectric conversion apparatus 1403, an image processing circuit 1404, a monitor 1405, and a memory 1406. Then, the distance image sensor 1401 can receive light (modulated light or pulsed light) projected from a light source apparatus 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion apparatus 1403 and forms an image on the light-receiving surface (sensor portion) of the photoelectric conversion apparatus 1403.

As the photoelectric conversion apparatus 1403, the photoelectric conversion apparatus 100 of each of the above-described embodiments is applied, and a distance signal indicating a distance obtained from a light reception signal output from the photoelectric conversion apparatus 1403 is supplied to the image processing circuit 1404.

The image processing circuit 1404 performs image processing of creating a distance image based on the distance signal supplied from the photoelectric conversion apparatus 1403. Then, the distance image (image data) obtained by the image processing is supplied to and displayed on the monitor 1405, and supplied to and stored (recorded) in the memory 1406.

The distance image sensor 1401 having such configuration can acquire, for example, a more correct distance image along with improvement in characteristic of pixels by applying the above-described photoelectric conversion apparatus 100.

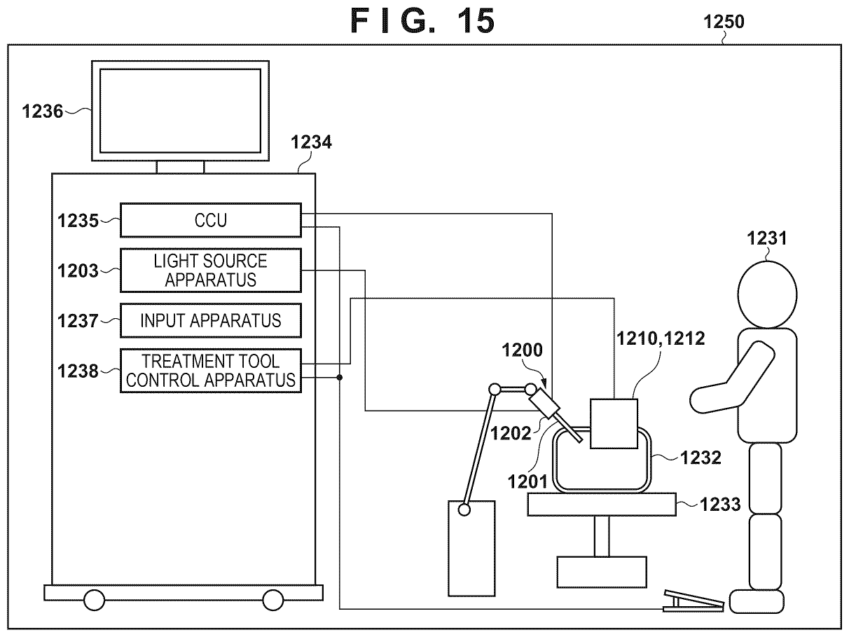

FIG. 15 is a view showing an example of the schematic configuration of an endoscopic surgery system 1250 as the photoelectric conversion system. FIG. 15 shows a state in which an operator (doctor) 1231 operates on a patient 1232 on a patient bed 1233 using the endoscopic surgery system 1250. As shown in FIG. 15, the endoscopic surgery system 1250 is formed from an endoscope 1200, a surgical tool 1210, and a cart 1234 on which various apparatuses for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 15, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source apparatus 1203 is connected to the endoscope 1200, and light generated by the light source apparatus 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion apparatus are provided in the camera head 1202, and reflected light (observation light) from the observation target is condensed by the optical system to the photoelectric conversion apparatus. The observation light is photoelectrically converted by the photoelectric conversion apparatus to generate an electrical signal corresponding to the observation light, that is, an image signal corresponding to an observation image. As the photoelectric conversion apparatus, the photoelectric conversion apparatus 100 (image capturing apparatus) described in each of the above-described embodiments can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display apparatus 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display apparatus 1236 displays the image based on the image signal having undergone the image processing by the CCU 1235.

The light source apparatus 1203 is formed from a light source such as a Light Emitting Diode (LED), and supplies, to the endoscope 1200, irradiation light at the time of imaging an operation portion or the like.

An input apparatus 1237 is an input interface to the endoscopic surgery system 1250. The user can input various kinds of information or instructions to the endoscopic surgery system 1250 via the input apparatus 1237.

A treatment tool control apparatus 1238 controls driving of an energy treatment tool 1212 for ablation or incision of the tissue, sealing of a blood vessel, or the like.

The light source apparatus 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source apparatus 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source apparatus 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source apparatus 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing irradiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source apparatus 1203 can be configured to supply narrow band light and/or excitation light corresponding to such special light observation.

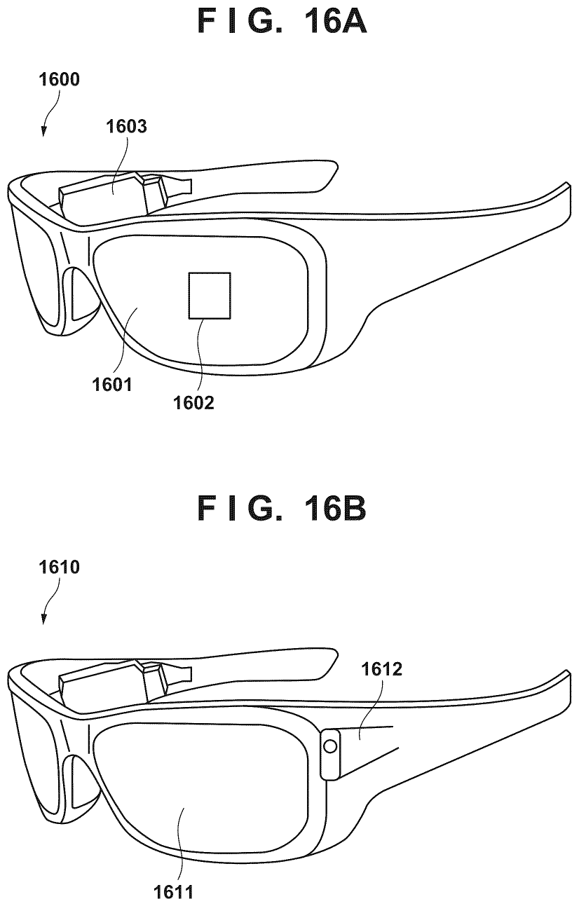

FIGS. 16A and 16B each describe glasses 1600 (smartglasses) as the photoelectric conversion system. The glasses 1600 shown in FIG. 16A include a photoelectric conversion apparatus 1602. The photoelectric conversion apparatus 1602 is the photoelectric conversion apparatus 100 (image capturing apparatus) described in each of the above-described embodiments. A display apparatus including the light emitting apparatus such as an OLED or LED may be provided on the back surface side of a lens 1601. One or a plurality of photoelectric conversion apparatuses 1602 may be provided. Alternatively, a plurality of kinds of photoelectric conversion apparatuses may be used in combination. The arrangement position of the photoelectric conversion apparatus 1602 is not limited to that shown in FIG. 16A.

The glasses 1600 further include a control apparatus 1603. The control apparatus 1603 functions as a power supply that supplies electric power to the photoelectric conversion apparatus 1602 and the above-described display apparatus. In addition, the control apparatus 1603 controls the operations of the photoelectric conversion apparatus 1602 and the display apparatus. An optical system configured to condense light to the photoelectric conversion apparatus 1602 is formed on the lens 1601.

FIG. 16B describes glasses 1610 (smartglasses) according to one application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system configured to project light emitted from the display apparatus are formed in a lens 1611, and an image is projected to the lens 1611. The control apparatus 1612 functions as a power supply that supplies electric power to the photoelectric conversion apparatus and the display apparatus, and controls the operations of the photoelectric conversion apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to the embodiment can include a photoelectric conversion apparatus including a light receiving element, and control a displayed image of the display apparatus based on the line-of-sight information of the user from the photoelectric conversion apparatus.

More specifically, the display apparatus decides a first visual field region at which the user is gazing and a second visual field region other than the first visual field region based on the line-of-sight information. The first visual field region and the second visual field region may be decided by the control apparatus of the display apparatus, or those decided by an external control apparatus may be received. In the display region of the display apparatus, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead the line of sight from the image of the eyeball using the image of the eyeball and the direction of actual viewing of the eyeball in the image as supervised data. The AI program may be held by the display apparatus, the photoelectric conversion apparatus, or an external apparatus. If the external apparatus holds the AI program, it is transmitted to the display apparatus via communication.

If display control is performed based on line-of-sight detection, this can be applied to smartglasses further including a photoelectric conversion apparatus configured to capture the image of the outside. The smartglasses can display the captured outside image information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-034179, filed Mar. 6, 2024, which is hereby incorporated by reference herein in its entirety.

What is claimed is:

1. A back-illuminated type photoelectric conversion apparatus in which a first semiconductor layer including an APD array in which a plurality of avalanche photodiodes (APDs) are arranged, a second semiconductor layer including a plurality of first pixel circuits respectively for the plurality of APDs, a third semiconductor layer including a plurality of second pixel circuits respectively for the plurality of first pixel circuits, and a fourth semiconductor layer including a processing circuit configured to process signals output from the plurality of second pixel circuits are stacked, wherein
the second semiconductor layer is arranged between the first semiconductor layer and the fourth semiconductor layer,
the third semiconductor layer is arranged between the second semiconductor layer and the fourth semiconductor layer, and
a through via extending through the third semiconductor layer is arranged in a region not overlapping the APD array.

2. The apparatus according to claim 1, wherein the plurality of second pixel circuits are arranged on a surface of the third semiconductor layer on a side of the second semiconductor layer.

3. The apparatus according to claim 1, wherein with respect to the plurality of first pixel circuits, one first pixel circuit is arranged in correspondence with each of the plurality of APDs or one first pixel circuit is arranged in correspondence with one group constituted by a predetermined number of APDs among the plurality of APDs.

4. The apparatus according to claim 1, wherein the processing circuit is arranged on a surface of the fourth semiconductor layer on a side of the third semiconductor layer.

5. The apparatus according to claim 1, wherein a memory configured to store the signals output from the plurality of second pixel circuits is arranged in the fourth semiconductor layer.

6. The apparatus according to claim 5, wherein
the memory includes a first memory and a second memory configured to store the signals output from the plurality of second pixel circuits or signals obtained by processing the signals output from the plurality of second pixel circuits, and
the processing circuit is arranged between the first memory and the second memory.

7. The apparatus according to claim 1, further comprising:
one pad electrode configured to supply a common potential to the third semiconductor layer and the fourth semiconductor layer.

8. The apparatus according to claim 7, wherein the common potential is a ground potential.

9. The apparatus according to claim 1, wherein a pad electrode exposed via an opening formed in the first semiconductor layer and connected to the plurality of APDs is arranged between the first semiconductor layer and the second semiconductor layer.

10. The apparatus according to claim 1, wherein the second semiconductor layer is thinner than the third semiconductor layer.

11. The apparatus according to claim 1, wherein the third semiconductor layer is thinner than the fourth semiconductor layer.

12. The apparatus according to claim 1, wherein a width of the through via extending through the third semiconductor layer is larger than a width of a through via extending through the second semiconductor layer.

13. The apparatus according to claim 1, wherein in a planar view, a total area of the through via provided in the third semiconductor layer is smaller than a total area of the through via provided in the second semiconductor layer.

14. The apparatus according to claim 1, wherein
a signal transfer unit configured to transfer the signals output from the plurality of second pixel circuits to the fourth semiconductor layer is arranged in the third semiconductor layer, and
the signal transfer unit is arranged in a region not overlapping the APD array.

15. The apparatus according to claim 14, wherein in a planar view, the signal transfer unit is arranged along a long side of the APD array.

16. The apparatus according to claim 1, wherein the processing circuit is arranged to overlap the APD array.

17. The apparatus according to claim 1, wherein a phase synchronization circuit configured to control an operation timing of the overall photoelectric conversion apparatus is arranged in the fourth semiconductor layer.

18. The apparatus according to claim 1, wherein a phase synchronization circuit is arranged in each of the third semiconductor layer and the fourth semiconductor layer.

19. A photoelectric conversion system comprising:
a photoelectric conversion apparatus defined in claim 1; and
a signal processing unit configured to generate an image using a signal output by the photoelectric conversion apparatus.

20. A moving body that includes a photoelectric conversion apparatus defined in claim 1, comprising:
a control unit configured to control movement of the moving body using a signal output by the photoelectric conversion apparatus.

21. Equipment that comprises a photoelectric conversion apparatus defined in claim 1, further comprising at least one of:
an optical apparatus corresponding to the photoelectric conversion apparatus;
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store information obtained by the photoelectric conversion apparatus; and
a mechanical apparatus configured to operate based on information obtained by the photoelectric conversion apparatus.
